(19) United States
(12) Patent Application Publication
(10) Pub. No.: US 2026/0305279 A1
(43) Pub. Date: Oct. 1, 2026

(54) DIRECTLY ELECTROPLATED THROUGH-HOLE VIA AND METHOD

(71) Applicant: Raytheon Company, Arlington, VA (US)

(72) Inventors: Andrew D. Spaeth, Holden, MA (US); Joseph V. Mantese, Ellington, CT (US)

(21) Appl. No.: 19/097,490

(22) Filed: Apr. 1, 2025

(51) Int. Cl. H10W 20/00; H10W 20/20

(52) U.S. Cl. CPC H10W 20/023; H10W 20/057; H10W 20/20

(57) ABSTRACT

A method includes coupling a wafer including a through-hole to a conductive substrate. The method also includes directly electroplating a through-hole via within the through-hole. The through-hole includes sidewalls formed by the wafer and a base formed by the conductive substrate, and no metallic seed layer is formed between the sidewalls and the through-hole via.

### TECHNICAL FIELD

This disclosure relates generally to via formation in semiconductor fabrication. More specifically, this disclosure relates to a directly electroplated through-hole via and method.

### BACKGROUND

Semiconductor fabrication generally includes the formation and metallization of through-silicon vias or through-chip vias. This process typically includes via formation by drilling partially through a substrate (commonly silicon). A metallic seed layer is then deposited over the substrate, after which electroplating with an engineered electroplating bath is performed to fill the vias. This current approach for filling vias is generally limited to copper electroplating baths. In addition, this approach builds copper upward from bases of the vias and also inward from sidewalls of the vias, which can create voids that trap the acidic electroplating solution. Because of this, the electroplating bath generally includes a package of organic additives to minimize voids.

### SUMMARY

This disclosure relates to a directly electroplated through-hole via and method.

In a first embodiment, a method may include coupling a wafer including a through-hole to a conductive substrate. The method may also include directly electroplating a through-hole via within the through-hole. The through-hole may include sidewalls formed by the wafer and a base formed by the conductive substrate, and no metallic seed layer may be formed between the sidewalls and the through-hole via.

Any single one or any combination of the following features may be used with the first embodiment. Coupling the wafer to the conductive substrate may include coupling the wafer to the conductive substrate using wafer bonding, an adhesive or photoresist. Directly electroplating the through-hole via may include directly electroplating the through-hole via using an electroplating bath without a void-preventing organic additives package. The wafer may include one of silicon (Si), silicon carbide (SiC), gallium nitride (GaN), gallium arsenide (GaAs), aluminum nitride (AlN), glass, sapphire, or diamond. The conductive substrate may include one of a metal-coated glass slide or a carrier wafer with a physical vapor deposition (PVD) metal layer. The through-hole via may include copper. The through-hole via may include one of nickel, gold, palladium, tin, platinum, or mixture thereof. The method may include, subsequent to directly electroplating the through-hole via, removing the conductive substrate from the wafer.

In a second embodiment, a method may include forming a through-hole from an upper surface of a wafer to a lower surface of the wafer. The method may also include coupling the wafer to a conductive substrate such that the through-hole includes sidewalls formed by the wafer and a base formed by the conductive substrate. The method may further include forming a through-hole via within the through-hole, and no metallic seed layer may be formed between the sidewalls and the through-hole via.

Any single one or any combination of the following features may be used with the second embodiment. Coupling the wafer to the conductive substrate may include coupling the wafer to the conductive substrate using wafer bonding, an adhesive or photoresist. Forming the through-hole via may include forming the through-hole via using an electroplating bath without a void-preventing organic additives package. The wafer may include one of Si, SiC, GaN, GaAs, AlN, glass, sapphire, or diamond. The conductive substrate may include one of a metal-coated glass slide or a carrier wafer with a PVD metal layer. The through-hole via may include copper. The through-hole via may include one of nickel, gold, palladium, tin, platinum, or mixture thereof. The method may include, subsequent to forming the through-hole via, removing the conductive substrate from the wafer.

In a third embodiment, a wafer may include a plurality of directly-electroplated through-hole vias. Each of the plurality of directly-electroplated through-hole vias may be formed within a corresponding through-hole through the wafer. For each directly-electroplated through-hole via, no metallic seed layer may be formed between sidewalls of the corresponding through-hole and the directly-electroplated through-hole via.

Any single one or any combination of the following features may be used with the third embodiment. The wafer may include one of Si, SiC, GaN, GaAs, AlN, glass, sapphire, or diamond. Each of the through-hole vias may include copper. Each of the through-hole vias may include one of nickel, gold, palladium, tin, platinum, or mixture thereof.

Other technical features may be readily apparent to one skilled in the art from the following figures, descriptions, and claims.

### BRIEF DESCRIPTION OF THE DRAWINGS

For a more complete understanding of this disclosure, reference is made to the following description, taken in conjunction with the accompanying drawings, in which:

FIGS. 1A-1G are a series of schematic cross-sectional diagrams illustrating an example of a process for directly electroplating through-hole vias according to this disclosure; and

FIG. 2 illustrates an example of a method for providing direct electroplating of through-hole vias according to this disclosure.

### DETAILED DESCRIPTION

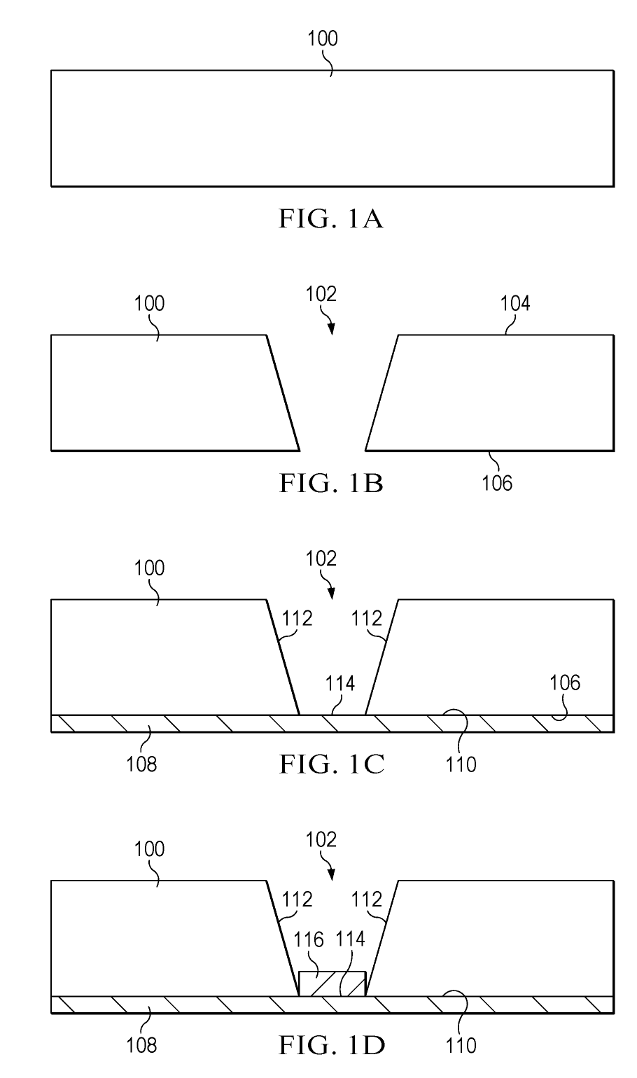

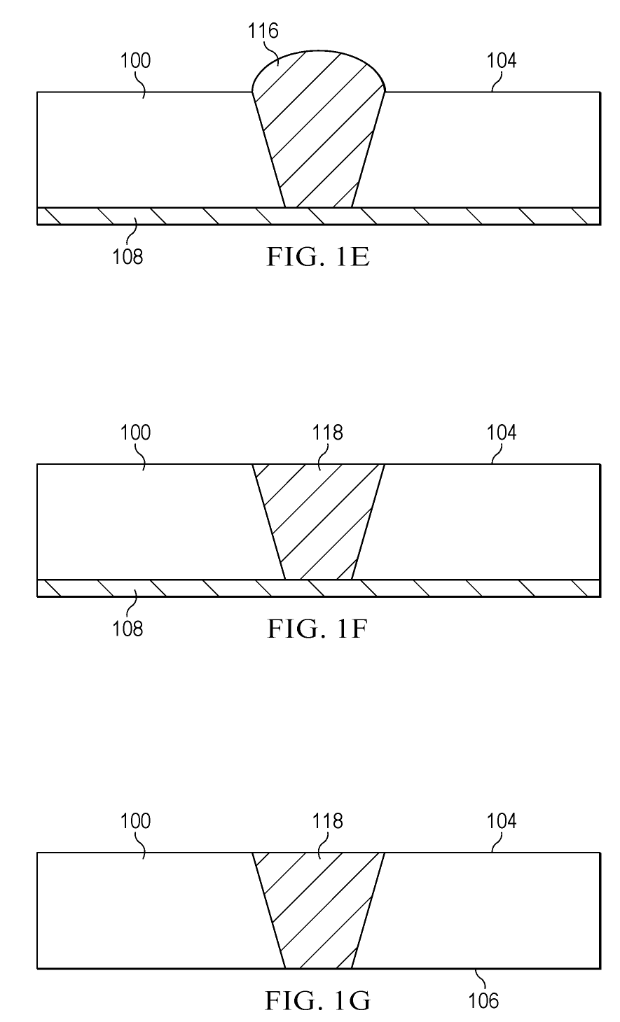

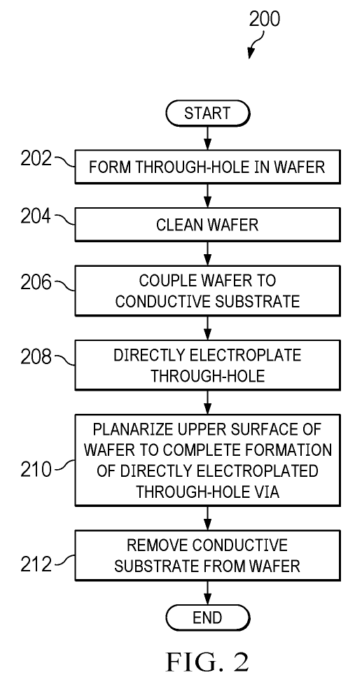

FIGS. 1A-2, described below, and the various embodiments used to describe the principles of the present disclosure are by way of illustration only and should not be construed in any way to limit the scope of this disclosure. Those skilled in the art will understand that the principles of the present disclosure may be implemented in any type of suitably arranged device or system.

As noted above, semiconductor fabrication generally includes the formation and metallization of through-silicon vias or through-chip vias. This process typically includes via formation by drilling partially through a substrate (commonly silicon). A metallic seed layer is then deposited over the substrate, after which electroplating with an engineered electroplating bath is performed to fill the vias. This current approach for filling vias is generally limited to copper electroplating baths. In addition, this approach builds copper upward from bases of the vias and also inward from sidewalls of the vias, which can create voids that trap the acidic electroplating solution. Because of this, the electroplating bath generally includes a package of organic additives to minimize voids.

This disclosure provides for directly electroplated through-hole vias and methods for forming these through-hole vias. As described in more detail below, in some embodiments, a wafer including a through-hole can be coupled to a conductive substrate. A through-hole via can be directly electroplated within the through-hole. The through-hole can include sidewalls formed by the wafer and a base formed by the conductive substrate, and no metallic seed layer can be formed between the sidewalls and the through-hole via.

The disclosed techniques allow for greater diversity in electroplating metal options for through-hole via filling, especially for higher temperatures or corrosion resistant metals. By coupling a conductive substrate to the wafer to form a conductive base for the through-hole, the need for a metallic seed layer over the wafer and the through-hole is eliminated. Metal formation can be provided upward from the base but not inward from via sidewalls, which allows direct electroplating of each via without the need for a void-preventing organic additives package. In addition, these approaches open new design spaces with not only different metals but also with different wafer material options and the ability to provide higher aspect ratio through-holes due to the upward metallization process.

FIGS. 1A-1G are a series of schematic cross-sectional diagrams illustrating an example of a process for directly electroplating through-hole vias according to this disclosure. The embodiment of the process shown in FIGS. 1A-1G is for illustration only. Other embodiments of the process may be used without departing from the scope of this disclosure.

Referring to FIG. 1A, a wafer 100 is provided. The wafer 100 can include silicon (Si), silicon carbide (SIC), gallium nitride (GaN), gallium arsenide (GaAs), aluminum nitride (AlN), glass, sapphire, diamond, or any other suitable wafer material. Referring to FIG. 1B, a through-hole 102 can be drilled or otherwise formed through the wafer 100. The through-hole 102 can be drilled using a laser, by reactive ion etching, or with any other suitable technique. The through-hole 102 can extend from an upper surface 104 of the wafer 100 completely through to a lower surface 106 of the wafer 100. Although the illustrated embodiment includes one through-hole 102, multiple through-holes 102 can be formed through the wafer 100 based on the number of through-hole vias desired in the final structure.

Referring to FIG. 1C, the wafer 100 can be coupled to a conductive substrate 108. The conductive substrate 108 may include a conductive material on at least an upper surface 110 of the conductive substrate 108. For example, the conductive substrate 108 may include a metal-coated glass slide, a carrier wafer with a physical vapor deposition (PVD) metal layer on at least one side of the carrier wafer, or any other suitable substrate having a conductive material on at least the upper surface 110. The wafer 100 can be coupled to the conductive substrate 108 using any suitable technique. For example, the wafer 100 and the conductive substrate 108 can be taped together at their edges, coupled together with wafer bonding, an adhesive or photoresist, or held together in any other suitable manner. The through-hole 102 can include sidewalls 112 formed by the wafer 100 where the wafer 100 has been drilled through to form the through-hole 102. In addition, while the wafer 100 is coupled to the conductive substrate 108, the through-hole 102 can include a base 114 formed by an exposed portion of the upper surface 110 of the conductive substrate 108.

Referring to FIG. 1D, electroplating can be provided by any common electroplating bath to begin formation of the through-hole via. In some embodiments, the electroplating bath can include no void-preventing organic additives package. As used herein, a “void-preventing organic additives package” means an organic additives package configured to prevent the formation of voids or seams during via filling. For example, in some conventional via formation processes, copper electroplating baths can include a void-preventing organic additives package that is configured to prevent the formation of voids or seams, especially for high aspect ratio vias, such as vias with aspect ratios greater than 5:1. As illustrated in FIG. 1D, a metal 116 can begin to form upward from the base 114 of the through-hole 102. Thus, instead of using a metallic seed layer deposited over the wafer 100 and the through-hole 102, the metal 116 can form over the conductive material of the exposed portion of the upper surface 110 of the conductive substrate 108 and fill in an upward direction without forming in an inward direction from the sidewalls 112 of the through-hole 102. Depending on which electroplating bath is used, the metal 116 may include copper, nickel, gold, palladium, tin, platinum, any other suitable metal, or an alloy of any of these.

Referring to FIG. 1E, after electroplating has been completed, the through-hole 102 may be substantially filled with the metal 116 such that a portion of the metal 116 may extend above the upper surface 104 of the wafer 100. Referring to FIG. 1F, the upper surface 104 of the wafer 100 may be cleaned by chemical mechanical polishing (CMP) or any other suitable technique. After cleaning, the upper surface 104 of the wafer 100 may be planarized such that the metal 116 extending above the upper surface 104 is removed, leaving a completed through-hole via 118 in the wafer 100. Thus, the through-hole via 118 includes the material of the metal 116 formed during electroplating.

Referring to FIG. 1G, the conductive substrate 108 can be removed from the wafer 100. In some embodiments, the upper surface 104 of the wafer 100 can be mounted to a carrier wafer to allow removal of the conductive substrate 108. In particular embodiments, the conductive substrate 108 can be removed using CMP or other suitable technique. In embodiments in which the conductive substrate 108 has been taped to the wafer 100, the tape can be removed to uncouple the conductive substrate 108 from the wafer 100. After removal of the conductive substrate 108, the through-hole via 118 can provide an electrical coupling from the upper surface 104 to the lower surface 106 of the wafer 100.

In this way, the through-hole 102 can be directly electroplated to form the through-hole via 118 without the use of a metallic seed layer. Moreover, the through-hole 102 can be plated from the base 114 of the through-hole 102 upward without being plated inward from the sidewalls 112, eliminating the possibility of voids forming and trapping the electroplating solution inside the through-hole via 118. Because of this, electroplating of the through-hole via 118 can be done without the need for including a conventional engineered, void-preventing organic additives package in the electroplating bath. Also, the wafer 100 is not limited to silicon, the metal 116 is not limited to copper, and higher aspect ratio through-holes 102 are possible because of the upward metallization process.

Although FIGS. 1A-1G illustrate one example of a process for directly electroplating through-hole vias 118, various changes may be made to FIGS. 1A-1G. For example, as previously noted, multiple through-hole vias 118 may be formed in the wafer 100. Also, note that the views shown in FIGS. 1A-1G are not to scale.

FIG. 2 illustrates an example of a method 200 for providing direct electroplating of through-hole vias according to this disclosure. As shown in FIG. 2, a through-hole is formed in a wafer at step 202. This may include, for example, a wafer 100 being drilled to create a through-hole 102. The through-hole can be formed in the wafer 100 using a laser, reactive ion etching, or any other suitable technique. The wafer 100 can include Si, SiC, GaN, GaAs, AlN, glass, sapphire, diamond, or any other suitable wafer material.

The wafer is cleaned at step 204. This may include, for example, cleaning the wafer 100 using an ultrasonic process involving a solvent, such as isopropanol, acetone, or the like. The wafer 100 can also be dried using nitrogen gas or other suitable drying techniques. In some embodiments, the wafer 100 can be cleaned using ultraviolet light or a plasma cleaner with an air or oxygen source for a period of about ten minutes, which can decrease the water contact angle of the wafer 100. The wafer 100 may also be cleaned using any other suitable cleaning technique instead of, or in addition to, any of these.

The wafer is coupled to a conductive substrate at step 206. This may include, for example, a lower surface 106 of the wafer 100 being coupled to an upper surface 110 of a conductive substrate 108. The wafer 100 can be coupled to the conductive substrate 108 using any suitable technique. For example, the wafer 100 and the conductive substrate 108 can be taped together at their edges, coupled together with an adhesive or photoresist, wafer bonded, or held together in any other suitable way. In some embodiments, the conductive substrate 108 can include a copper-coated or other metal-coated glass slide. In other embodiments, the conductive substrate 108 can include a carrier wafer with a PVD copper or other metal layer on at least one side of the carrier wafer. The conductive substrate 108 can also include any other suitable substrate having a conductive material on at least the upper surface 110 of the conductive substrate 108.

The through-hole is directly electroplated at step 208. This may include, for example, a metal 116 being formed in the through-hole 102 by using an electroplating bath. In some embodiments, the electroplating bath can include no void-preventing organic additives package. During electroplating, the metal 116 can be formed upward into the through-hole 102 from the base 114 of the through-hole 102, which is formed by the upper surface 110 of the conductive substrate 108. The metal 116 can continue to be formed upward until the metal 116 rises above an upper surface 104 of the wafer 100. Note that, during electroplating, the metal 116 can also be prevented from forming inward from the sidewalls 112 of the through-hole 102 by the absence of any metallic seed layer formed over the wafer 100 and along the sidewalls 112. In some embodiments, depending on the electroplating bath used, the metal 116 may include copper, nickel, gold, palladium, tin, platinum, any other suitable metal, or an alloy of any of these.

The upper surface of the wafer is planarized to complete formation of a directly electroplated through-hole via at step 210. This may include, for example, planarizing the upper surface 104 of the wafer 100 to remove the metal 116 above the upper surface 104 to complete the formation of the through-hole via 118. In some embodiments, the upper surface 104 of the wafer 100 can be planarized by using CMP or any other suitable technique. The conductive substrate is removed from the wafer at step 212. This may include, for example, the conductive substrate 108 being removed from the wafer 100 using CMP or any other suitable technique. This may instead include, for example, the removal of any tape coupling the conductive substrate 108 to the wafer 100. At this point, the through-hole via 118, which includes the metal 116, extends through the wafer 100, providing an electrical pathway from the upper surface 104 to the lower surface 106 of the wafer 100.

In this way, the through-hole 102 can be directly electroplated to form the through-hole via 118 without the use of a metallic seed layer. The through-hole 102 can also be plated from the base 114 of the through-hole 102 upward without being plated inward from the sidewalls 112, eliminating voids that could trap the electroplating solution inside the through-hole via 118. Further, electroplating of the through-hole via 118 can be done without the need for the conventional engineered, void-preventing organic additives package. In addition, the wafer 100 is not limited to silicon, the metal 116 is not limited to copper, and higher aspect ratio through-holes 102 are possible based on the upward metallization process.

Although FIG. 2 illustrates one example of a method 200 for providing direct electroplating of through-hole vias, various changes may be made to FIG. 2. For example, although described as directly electroplating one through-hole via 118, any suitable number of through-hole vias 118 can be directly electroplated for the wafer 100. Also, in some embodiments for particular applications, the conductive substrate 108 may remain coupled to the wafer 100 and step 212 may be omitted. In addition, while shown as a series of steps, various steps in FIG. 2 may overlap, occur in parallel, occur in a different order, or occur any number of times (including zero times).

It may be advantageous to set forth definitions of certain words and phrases used throughout this patent document. The term “about” (when used with a numerical value) indicates that the numerical value may vary by up to ±10%. The terms “include” and “comprise,” as well as derivatives thereof, mean inclusion without limitation. The term “or” is inclusive, meaning and/or. The phrase “associated with,” as well as derivatives thereof, may mean to include, be included within, interconnect with, contain, be contained within, connect to or with, couple to or with, be communicable with, cooperate with, interleave, juxtapose, be proximate to, be bound to or with, have, have a property of, have a relationship to or with, or the like. The phrase “at least one of,” when used with a list of items, means that different combinations of one or more of the listed items may be used, and only one item in the list may be needed. For example, “at least one of: A, B, and C” includes any of the following combinations: A, B, C, A and B, A and C, B and C, and A and B and C.

The description in the present application should not be read as implying that any particular element, step, or function is an essential or critical element that must be included in the claim scope. The scope of patented subject matter is defined only by the allowed claims. Moreover, none of the claims invokes 35 U.S.C. § 116(f) with respect to any of the appended claims or claim elements unless the exact words “means for” or “step for” are explicitly used in the particular claim, followed by a participle phrase identifying a function. Use of terms such as (but not limited to) “mechanism,” “module,” “device,” “unit,” “component,” “element,” “member,” “apparatus,” “machine,” “system,” “processor,” or “controller” within a claim is understood and intended to refer to structures known to those skilled in the relevant art, as further modified or enhanced by the features of the claims themselves, and is not intended to invoke 35 U.S.C. § 116(f).

While this disclosure has described certain embodiments and generally associated methods, alterations and permutations of these embodiments and methods will be apparent to those skilled in the art. Accordingly, the above description of example embodiments does not define or constrain this disclosure. Other changes, substitutions, and alterations are also possible without departing from the spirit and scope of this disclosure, as defined by the following claims.

What is claimed is:

1. A method comprising:
coupling a wafer comprising a through-hole to a conductive substrate; and
directly electroplating a through-hole via within the through-hole;
wherein the through-hole comprises sidewalls formed by the wafer and a base formed by the conductive substrate; and
wherein no metallic seed layer is formed between the sidewalls and the through-hole via.

2. The method of claim 1, wherein coupling the wafer to the conductive substrate comprises coupling the wafer to the conductive substrate using wafer bonding, an adhesive or photoresist.

3. The method of claim 1, wherein directly electroplating the through-hole via comprises directly electroplating the through-hole via using an electroplating bath without a void-preventing organic additives package.

4. The method of claim 1, wherein the wafer comprises one of silicon, silicon carbide, gallium nitride, gallium arsenide, aluminum nitride, glass, sapphire, or diamond.

5. The method of claim 1, wherein the conductive substrate comprises one of a metal-coated glass slide or a carrier wafer with a physical vapor deposition (PVD) metal layer.

6. The method of claim 1, wherein the through-hole via comprises copper.

7. The method of claim 1, wherein the through-hole via comprises one of nickel, gold, palladium, tin, platinum, or mixture thereof.

8. The method of claim 1, further comprising:
subsequent to directly electroplating the through-hole via, removing the conductive substrate from the wafer.

9. A method comprising:
forming a through-hole from an upper surface of a wafer to a lower surface of the wafer;
coupling the wafer to a conductive substrate such that the through-hole comprises sidewalls formed by the wafer and a base formed by the conductive substrate; and
forming a through-hole via within the through-hole, wherein no metallic seed layer is formed between the sidewalls and the through-hole via.

10. The method of claim 9, wherein coupling the wafer to the conductive substrate comprises coupling the wafer to the conductive substrate using wafer bonding, an adhesive or photoresist.

11. The method of claim 9, wherein forming the through-hole via comprises forming the through-hole via using an electroplating bath without a void-preventing organic additives package.

12. The method of claim 9, wherein the wafer comprises one of silicon, silicon carbide, gallium nitride, gallium arsenide, aluminum nitride, glass, sapphire, or diamond.

13. The method of claim 9, wherein the conductive substrate comprises one of a metal-coated glass slide or a carrier wafer with a physical vapor deposition (PVD) metal layer.

14. The method of claim 9, wherein the through-hole via comprises copper.

15. The method of claim 9, wherein the through-hole via comprises one of nickel, gold, palladium, tin, platinum, or mixture thereof.

16. The method of claim 9, further comprising:
subsequent to forming the through-hole via, removing the conductive substrate from the wafer.

17. A wafer comprising:
a plurality of directly-electroplated through-hole vias;
wherein each of the plurality of directly-electroplated through-hole vias is formed within a corresponding through-hole through the wafer; and
wherein, for each directly-electroplated through-hole via, no metallic seed layer is formed between sidewalls of the corresponding through-hole and the directly-electroplated through-hole via.

18. The wafer of claim 17, wherein the wafer comprises one of silicon, silicon carbide, gallium nitride, gallium arsenide, aluminum nitride, glass, sapphire, or diamond.

19. The wafer of claim 17, wherein each of the directly-electroplated through-hole vias comprises copper.

20. The wafer of claim 17, wherein each of the directly-electroplated through-hole vias comprises one of nickel, gold, palladium, tin, platinum, or mixture thereof.
